(19) United States
(12) Patent Application Publication
(10) Pub. No.: US 2025/0079241 A1
(43) Pub. Date: Mar. 6, 2025

(54) METHOD FOR PRODUCING A POWER COMPONENT BASED ON A WIDE BANDGAP SEMICONDUCTOR AND A POWER COMPONENT

(71) Applicant: Robert Bosch GmbH, Stuttgart (DE)

(72) Inventors: Kevin Dannecker, Reutlingen (DE); Max Reimer, Stuttgart (DE)

(21) Appl. No.: 18/797,747

(22) Filed: Aug. 8, 2024

(30) Foreign Application Priority Data
Sep. 6, 2023 (DE) 10 2023 208 586.0

(51) Int. Cl. H01L 21/78

(52) U.S. Cl. CPC H01L 21/7806

(57) ABSTRACT

A method for producing a power component based on a wide bandgap semiconductor. A device wafer with a substrate is provided. One or more functional layers are formed on the substrate that form the power component. At least one engineered layer is disposed between the functional layers and the substrate. The substrate is completely removed from the device wafer by selectively removing at least one engineered layer.

### CROSS REFERENCE

The present application claims the benefit under 35 U.S.C. § 119 of German Patent Application No. DE 10 2023 208 586.0 filed on Sep. 6, 2023, which is expressly incorporated herein by reference in its entirety.

### FIELD

The present invention relates to a method for producing an, in particular vertical, power component based on a wide bandgap semiconductor. The present invention also relates to a power component.

### BACKGROUND INFORMATION

Semiconductors with a wide bandgap (also referred to as wide bandgap semiconductors or WBG semiconductors or WBGS) are semiconductor materials that have a larger bandgap than conventional semiconductors. Conventional semiconductors such as silicon have a bandgap in the range of 0.6-1.5 electron volts (eV), whereas wide bandgap semiconductors have bandgaps in the range above 2 eV. Wide bandgap semiconductors usually have electronic properties that lie between those of conventional semiconductors and those of insulators.

Semiconductors with a wide bandgap generally enable devices to operate at higher voltages, frequencies, and temperatures than conventional semiconductor materials such as silicon and gallium arsenide.

Typical wide bandgap semiconductors are silicon carbide (SiC) and gallium nitride (GaN). A variety of other wide bandgap semiconductors are available to those skilled in the art. Transistors based on gallium nitride (GaN) make it possible to implement components that have lower on-resistances with simultaneously higher breakdown voltages than the comparable silicon-based or silicon carbide-based components. GaN transistors are primarily from so-called high-electron mobility transistors (HEMTs), in which the current flows laterally on the upper side of the substrate through a two-dimensional electron gas which forms the transistor channel. Such lateral components can be produced by heteroepitaxy of the functional GaN layers on silicon wafers.

For high breakdown voltage with low on-resistance per unit area, so-called vertical components, in which the current flows from the front of the substrate to the back of the substrate, are more advantageous, both in terms of size and the electric field distribution inside the component.

This cannot be achieved directly using heteroepitaxial GaN layers on silicon (Si), because insulating intermediate layers (a so-called buffer) are needed to adapt the lattice mismatch between GaN and Si and to reduce the substrate curvature. The buffer itself is mechanically tensioned in such a way that it just compensates the tensioning of the GaN layers at room temperature. However, since the buffer is an insulator, the buffer prevents the flow of current from the front to the back. There are currently native GaN substrates on which the required additional epitaxial GaN layers of the component can be grown without the need for an insulating buffer, but they are small (typically 50 mm in diameter) and comparatively expensive.

To reduce the transistor price per surface element, it is advantageous to use the available heteroepitaxial GaN layers on large silicon substrates. Vertical components for this purpose have been shown in the literature, see for example, Khadar et al., “Fully vertical GaN-on-Si power MOSFETs”, IEEE Electron Device Letters (2019), or Zhang et al., “720-V/0.35-mOhmcm\hat{ }2 Fully Vertical GaN-on-Si Power Didoes by Selective Removal of Si Substrates and Buffer Layers”, IEEE Electron Device Letters (2018). In vertical components produced in this way, the silicon substrate and the non-conductive buffer under the component are selectively removed in order to thus be able to directly contact the back of the drift zone of the component.

FIG. 1A shows the basic structure of such a component with an insulating buffer and a backside trench (here using the example of a trench MOSFET). The backside trench is also referred to as a backside cavity or backside aperture or recess. It goes without saying that the possibility of providing such conductive access to the back of a drift zone is not limited to this type of component, so that in principle any vertical power components can be produced using this technology.

For production, the following III-V nitride semiconductor layers (GaN with the exception of the buffer) are epitaxially grown on the silicon substrate 61 or generally the carrier substrate: the insulating buffer 33, a highly doped contact semiconductor layer with n-conductivity 34, a low-doped n-conductive drift layer 35, a p-conductive body layer 36, and a highly doped n-conductive source contact layer 37. A trench 51, the side walls and base of which are separated from the gate electrode 21 by a gate dielectric 22, passes through the source contact layer 37 and the body layer 36. The source contact layer 37 and the body layer 36 are contacted by a source electrode 41, which is separated from the gate electrode by an insulation layer 31.

On the back side, the silicon substrate and the buffer are removed by a backside trench 51, which ends in the highly conductive semiconductor contact layer 34. This is contacted by a backside drain electrode 52. During operation, a conductive channel is formed in the body layer 36 by applying a gate voltage to the gate electrode 21, through which a flow of current from the source electrode 41 to the drain electrode 52 is made possible. For the sake of simplicity, FIG. 1A shows a transistor with three cells, i.e. three repeating structures. In a real transistor, a large number of such cells are typically present and are therefore effectively connected in parallel. This makes it possible to reduce the resistance of the component and increase the current carrying capacity. Typical active surfaces are in the range of a few square millimeters; the remaining GaN layers are a few micrometers thick. This aspect ratio is difficult to depict in graphics. Drain electrode 52 can consist of a plurality of metallic layers and can also comprise a thickened metal. In the borderline case, the backside trench 51 can be completely filled with metal (not shown).

In the case of a not completely filled cavity, the described method results in a membrane having a thickness in the micrometer range and a lateral dimension of several millimeters. To protect these fragile membranes during processing, the wafer can be glued with its front side to a carrier wafer 63 by means of a connecting layer 62 before the trench 51 is created in the silicon, see FIG. 1B. This process is referred to in the following as temporary bonding.

After the silicon has been removed and the described metal layers have been applied, the transistor chips are singulated by sawing or laser dicing along so-called dicing lines or singulation lines to create separate chips.

Consisting of the above-described semiconductor and metal layers, the membrane has only limited stability. Processing, wafer handling and especially singulation, in which the wafer is singulated into the individual chips by means of dicing or laser dicing, can lead to deformations or bursting of the membranes, which can destroy or damage the components, or change parameters such as the threshold voltage.

### SUMMARY

An object of the present invention to provide a method for producing a power component based on a wide bandgap semiconductor such as GaN or GaO, which can advantageously be processed using established assembly and connection techniques such as sintering for the die attach process, wire bonding for the front side contacts, or even embedding, while at the same time having a particularly low thermal and electrical resistance. For this purpose, a layer structure and production method according to the present invention are proposed which in particular enable a vertical current flow in a power component, even if the component was grown heteroepitaxially on an insulating substrate or using insulating epitaxial intermediate layers. In contrast to the related art, this does not involve the creation of a cavity that is disadvantageous in terms of the thermal and electrical connection and also the use of the aforementioned established assembly and connection technologies.

Consisting of the above-described semiconductor and metal layers, a membrane has only limited stability. Processing, wafer handling and especially singulation, in which the wafer is singulated into the individual chips by means of dicing or laser dicing, can lead to deformations or bursting of the membranes, which can destroy or damage the components, or change parameters such as the threshold voltage.

Completely removing the substrate according to the present invention, allows the semiconductor layer to be stabilized more effectively and holistically later than would be the case for a membrane.

According to a first aspect of the present invention, a method for producing a power component based on a wide bandgap semiconductor is provided, wherein a device wafer with a substrate is provided. According to an example embodiment of the present invention, one or more functional layers are formed on the substrate that form the power component. At least one engineered layer is disposed between the functional layers and the substrate. According to the present invention, it is provided that the substrate is completely removed from the device wafer by selectively removing at least one engineered layer.

The present invention therefore provides a procedure for removing the active semiconductor layer from the substrate without destroying the substrate. The substrate typically accounts for a significant proportion of the cost and, with this method, it can be reused. The process can also be significantly cheaper, because it requires fewer process steps than completely or partially removing the substrate from the backside.

For GaN, for example, the approach of completely removing the substrate can be realized on so-called engineered substrates (e.g., QST wafers). This approach is also possible for gallium oxide (GaO) on foreign substrates.

Completely removing the substrate reduces the parasitic electrical resistance, in particular in a vertical power component, and improves the thermal connection to the circuit carrier, which is why the approach is also advantageous for lateral components.

The already applied layers are preferably stabilized by means of a carrier layer, in particular a carrier wafer, prior to removal of the substrate. For this purpose, temporary bonding to a glass or silicon wafer can be used, for example. This can advantageously ensure that the component is efficiently stabilized. Removing the bonding layer makes it easy to remove the carrier wafer and the power components can already be singulated and can be further processed immediately.

The device wafer can advantageously be debonded onto a dicing tape prior to the removal of the carrier wafer. This simplifies the singulation and the further processing even more.

A particularly preferred embodiment of a method according to the present invention comprises the following steps:
a. providing a device wafer (100) with a substrate (1), wherein one or more functional layers (4, 5, 6, 7, 8, 9, 10, 11, 12) are formed on the substrate (1) that form the power component and wherein at least one engineered layer (2, 3) is disposed between the functional layers (4, 5, 6, 7, 8, 9, 10, 11, 12) and the substrate (1),
b. forming at least one trench (23) through the functional layers (4, 5, 6, 7, 8, 9, 10, 11, 12), wherein the trench (23) extends to the engineered layer or layers (2, 3),
c. applying a passivation (13) to the surface of the device wafer (100) and the side walls of the at least one trench (23),
d. removing the passivation from the base (23′) of the at least one trench (23) and forming a depression (24) in the trench (23) such that the engineered layer or layers (2, 3) are exposed,
e. applying a carrier wafer (15) to the surface of the device wafer (100), wherein the carrier wafer (15) comprises openings (25) at defined locations through which an etching medium can be introduced into the trench (23) and the depression (24),
f. introducing an etching medium into the openings (25) and thereby removing at least one engineered layer (2, 3),
g. removing the device wafer (100) from the substrate (1), and
h. removing the individual power components.

In one possible embodiment of the present invention, at least one engineered layer is formed as a silicon layer. The silicon layer can be removed by introducing an etching medium comprising xenon difluoride gas.

In another possible embodiment of the present invention, at least one engineered layer is formed as a silicon oxide layer. The silicon oxide layer can be removed by introducing an etching medium comprising HF gas.

Any remaining engineered layers and/or buffer layers are preferably removed after the removal of the device wafer from the substrate, in particular by means of plasma etching.

After the removal of the device wafer from the substrate, one or more metallization layers can be applied to an exposed functional layer. If the power component is a MOSFET, for instance, a drain contact can efficiently be established.

According to a second aspect of the present invention, a power component based on a wide bandgap semiconductor is proposed, wherein the power component is produced using a method according to the first aspect and is in particular configured as a power transistor or as a diode. Examples of such power components include Schottky diodes, pn diodes, vertical diffusion MOSFETS (VDMOS), current aperture vertical electron transistors (CAVETs), vGroove vertical high electron mobility transistors or fin field effect transistors (FinFETs). Other examples are available to those skilled in the art.

The power component in particular comprises GaN or GaO or SiC as the functional semiconductor material, which in particular enables low losses in switching regulators, the processing of high voltages, operation at high (ambient) temperatures, the processing of higher frequencies and/or improved reliability.

### BRIEF DESCRIPTION OF THE DRAWINGS

Example embodiments of the present invention will be described in detail with reference to the figures.

FIGS. 1A and 1B show the production of a GaN trench MOSFET according to the related art.

FIGS. 2A-2H show the production of a vertical GaN MOSFET according to a possible embodiment of the present invention.

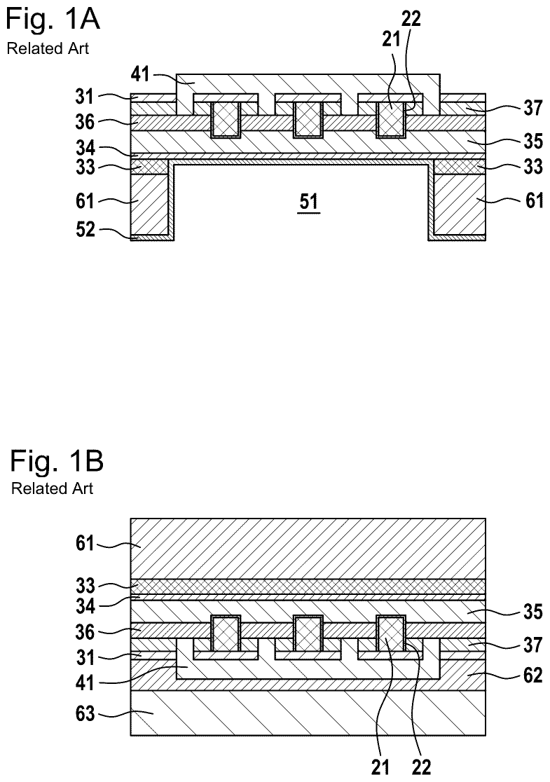

### DETAILED DESCRIPTION OF EXAMPLE EMBODIMENTS

In the following description of the embodiment examples of the present invention, the same elements are labeled with the same reference signs and a repeated description of these elements is omitted where appropriate. The figures show the subject matter of the present invention only schematically.

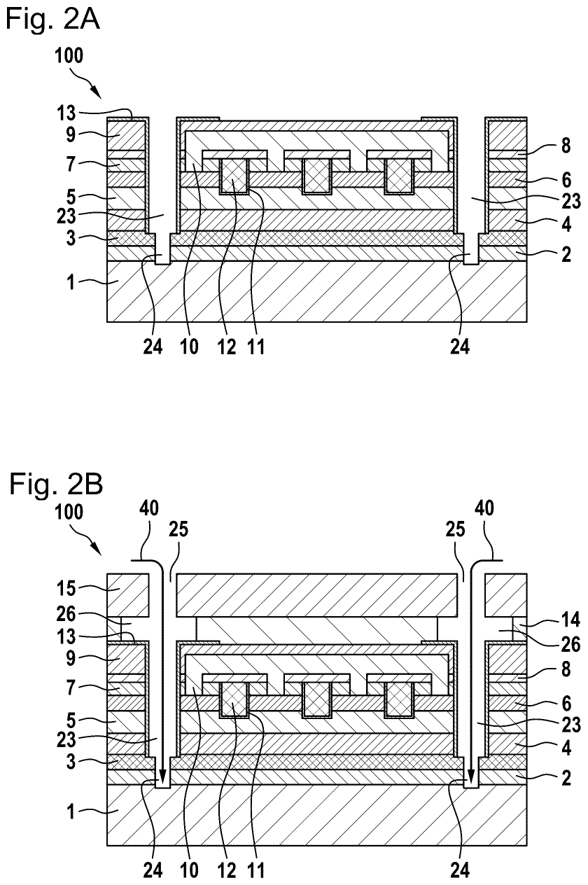

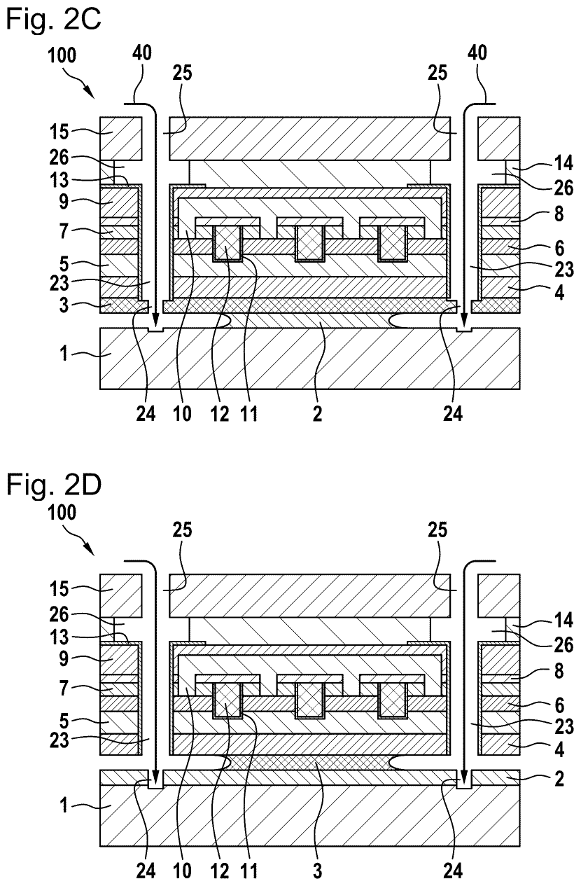

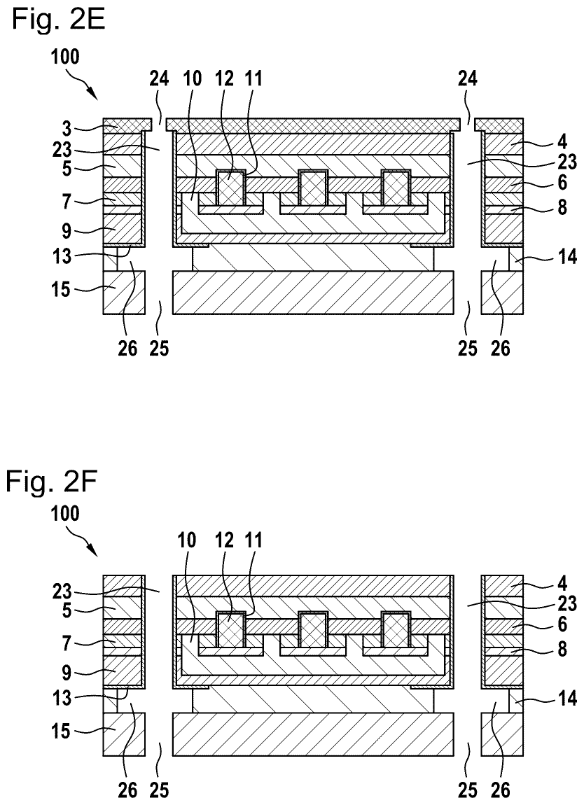

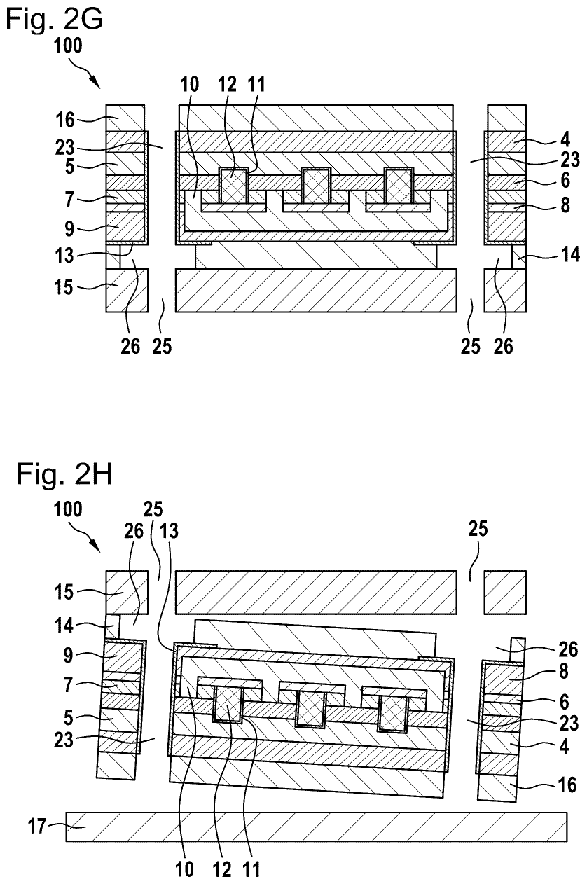

FIGS. 2A-2F show intermediate steps in a possible process flow for implementing the present invention described here using the example of the production of a GaN MOSFET as a vertical power component. First, a substrate 1 is provided on which multiple layers are formed. In the shown example, two so-called engineered layers 2 and 3 are formed on the substrate 1. A drain contact layer 4 and a drift layer 5 of the GaN epitaxy are disposed above the engineered layers 2, 3. Disposed above the drift layer 5 is a p-doped layer 6 of the semiconductor, above which an n-doped source layer 7 and an insulating layer 8 are disposed. The power metallization of the component is labeled 10; the gate dielectric is 11 and the gate electrode is 12.

After processing the front side, a stabilizing metal layer 9 can optionally be applied. First, etching is carried out along the dicing trenches 23 through all of the functional layers, including the epitaxial layers 5 and 4, and the side walls and the surface are protected with a passivation 13. This passivation 13 is then opened in a second etching on the base of the opening and the underlying engineered layers 2 and 3 are etched through to create a recess 24. The passivation 13 should not be removed anywhere else along the flank of the opening. Ideally, care should also be taken to open the passivation on the wafer surface in the region of the contact pads. Optionally, it is possible to carry out this etching procedure at another convenient time during the front-side processing and to protect the openings, e.g. by masking them, during the subsequent depositions.

In a next step (FIG. 2B), a carrier wafer 15 is applied to the front side of the device wafer 100, for example by means of a temporary bonding layer 14. Both the carrier wafer 15 and the bonding layer 14 have openings 25, 26, through which a gas can enter the previously etched trenches 23, 24 of the device wafer 100. The openings 25, 26 can be formed as holes at the intersections of dicing lines, for instance.

During the subsequent gas phase etching, the etching gas 40 is fed through these openings 25, 26, into the trenches 23, 24 toward the engineered layers 2, 3. The etching gas 40 and the material of the passivation 13 must be selected in such a way that a very high etching selectivity exists between them. An example would be silicon dioxide as the passivation, which is not etched in xenon difluoride (XeF₂). At the same time, however, at least one of the exposed engineered layers 2, 3 should be etched by the etching gas 40. As a rule, GaN epitaxy is started on a thin silicon layer, which is well etched by XeF₂. The process can alternatively be reversed, and an etching gas 40 such as hydrofluoric acid gas (HF gas) can be used to etch a SiO₂ layer in the engineered layers 2, 3. In this case, the passivation 13 can be selected as a polysilicon layer, for example, which is not etched in HF gas. Both variants are shown as examples in FIG. 2C for etching a silicon (layer 2) with XeF₂ or in FIG. 2D for etching a SiO₂ (layer 3) with HF gas.

The gas is then used to remove at least one of the engineered layers 2, 3 under the epitaxy between the openings in the device wafer 100. After complete removal, the device wafer 100 can be lifted off of the substrate 1.

As shown in FIG. 2E, the device wafer 100 is then turned over to remove any remaining layers (in this example the engineered layer 3) and buffer layers (not shown) (FIG. 2E). This can be done using plasma etching, for example.

Once the drain layer 4 of the epitaxy has been exposed (see FIG. 2F), a contact metal is applied as a metallization layer 16 and optionally a further stabilizing metal layer, as shown in FIG. 2G. The power component is now finished and the chips are already singulated because the initial etching reached the substrate 1. The device wafer 100 can now be turned over again and debonded onto a dicing tape 17, see FIG. 2H. After removing the carrier wafer 15, the bonding layer 14 is removed. The chips can then be taken off individually.

What is claimed is:

1. A method for producing a power component based on a wide bandgap semiconductor, the method comprising the following steps:
providing a device wafer with a substrate;
forming one or more functional layers on the substrate that form the power component;
disposing at least one engineered layer between the functional layers and the substrate;
completely removing the substrate from the device wafer by selectively removing at least one of the at least one engineered layer.

2. The method according to claim 1, wherein, prior to removal of the substrate, already applied layers are stabilized by a carrier layer, the carrier layer including a carrier wafer.

3. The method according to claim 1, further comprising the following steps:
forming at least one trench through the functional layers, wherein the trench extends to the at least one engineered layer;
applying a passivation to a surface of the device wafer and side walls of the at least one trench;
removing the passivation from a base of the at least one trench and forming a depression in the trench such that the at least one engineered layer is exposed;
applying a carrier wafer to the surface of the device wafer, wherein the carrier wafer includes openings at defined locations through which an etching medium can be introduced into the trench and the depression;
introducing the etching medium into the openings and thereby removing the at least one engineered layer;
removing the device wafer from the substrate; and
removing the power component.

4. The method according to claim 1, wherein at least one first engineered layer is formed as a silicon layer and the at least one first engineered layer is removed via an etching medium including xenon difluoride gas.

5. The method according to claim 4, wherein at least one second engineered layer is formed as a silicon oxide layer and the second engineered layer is removed via an etching medium including HF gas.

6. The method according to claim 3, wherein the carrier wafer is connected to the surface of the device wafer using a bonding layer.

7. The method according to claim 3, wherein, after the removal of the device wafer from the substrate, all remaining engineered layers and/or buffer layers are removed, using plasma etching.

8. The method according to claim 3, wherein, after the removal of the device wafer from the substrate, one or more metallization layers are applied to an exposed functional layer.

9. The method according to claim 3, wherein, after the removal of the device wafer from the substrate, the carrier wafer is removed.

10. The method according to claim 9, wherein, after the removal of the device wafer from the substrate, the bonding layer is removed.

11. The method according to claim 9, wherein, prior to the removal of the carrier wafer, the device wafer is debonded onto a dicing tape.

12. A power component based on a wide bandgap semiconductor, wherein the power component is produced by:
providing a device wafer with a substrate;
forming one or more functional layers on the substrate that form the power component;
disposing at least one engineered layer between the functional layers and the substrate;
completely removing the substrate from the device wafer by selectively removing at least one of the at least one engineered layer;
wherein the power component is a power transistor or as a diode.

13. The power component according to claim 12, wherein the power component includes GaN or GaO or SiC as functional semiconductor material.
